(19) United States
(12) Patent Application Publication
(10) Pub. No.: US 2008/0218194 A1
(43) Pub. Date: Sep. 11, 2008

(54) STACKED PACKAGE SCREENING

(75) Inventor: Takuyo KODAMA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/045,082

(22) Filed: Mar. 10, 2008

(30) Foreign Application Priority Data
Mar. 8, 2007 (JP) 2007-058514

(51) Int. Cl. G01R 31/26

(52) U.S. Cl. 324/765; 257/48

(57) ABSTRACT

A semiconductor device in which a plurality of devices provided with mutually identical functions are stacked includes: a chip selection terminal by which the semiconductor device selects devices, a prescribed terminal for generating a second internal signal that is selectively switched from a first internal signal from the chip selection terminal, and an input-switching circuit for selectively switching the first internal signal and the second internal signal.

This application is based upon and claims the benefit of priority from Japanese Patent Application No. 2007-058514 filed on Mar. 8, 2007, the content of which is incorporated by reference.

### BACKGROUND OF THE INVENTION

1. Field of the Invention

The present invention relates to a semiconductor device in which a plurality of devices are stacked and to a method of testing a semiconductor device.

2. Description of the Related Art

The increase in capacity of memory modules in recent years has seen advances in the development of stacked packages in which two devices can be put in one package. Stacked packages employ conventional device fabrication and enable the construction of a memory module of twice the capacity of a memory module realized by a conventional monolayer package. As a result, the development of this packaging technology is extremely effective. In order to allow selection of the upper device and lower device of a stacked package, a plurality of pins such as CSB pins to which a chip selection signal for selecting a device is applied as input, ODT pins for controlling termination resistance, and CKE pins for controlling whether an operation clock is valid/invalid are prepared in advance for the use of each of the upper device and lower device of the stacked package. As a result, a stacked package has more pins than a conventional monolayer package, and screening measurement environments that are adopted for the measurement of monolayer packages cannot be applied without modification to stacked packages.

JP-A-2003-257197A discloses a technology in which, in a semiconductor device that contain two memory chips, pins that are used in a semiconductor device that contains one memory chip are assigned to one device and NC (non-connect) pins are assigned to the other device to confer convertibility to a semiconductor device that contains one memory chip.

In addition, JP-A-2005-353168A discloses a technology in which a selector is used to control memory devices that use the same LSI but use different types of data-strobe signals.

However, the above-described technology of the related art has two problems as described below.

One of the problems is the great expense that is invested in facilities to prepare suitable measurement environments in which all input pins and output pins of an upper stacked package and lower stacked package are connected. This problem arises because the measurement environments for monolayer packages have been the mainstream in evaluating and screening and a great number of measurement environments have already been adopted for many factors, and in these measurement environments, there are input pins of devices that are not connected to the stacked package.

As the other problem, in screening or evaluating the devices of a stacked package in the measurement environments of a monolayer package, it is possible to apply input to a CSB pin from a tester to either of the devices in the stacked package, and operations can be brought about and output obtained. However, operations in the device in which the tester and the CSB pin are not connected are unstable, and the output is also unstable. The output of the device in which CSB pins are not connected to the tester and the output of the device in which CSB pins are connected to the tester are connected, and the problem may therefore occur that correct output data cannot be obtained for the output of the device that is operating due to the influence of the unstable output of the device that is not operating. This problem occurs due to the instability of the operation of the device in which CSB pins are not connected.

In addition, the problem occurs in the technology disclosed in JP-A-2003-257197A that a plurality of devices cannot be controlled when devices lacking NC pins are used.

The problem also occurs in the technology disclosed in JP-A-2005-353168A that selection signals for controlling the selector must be applied as input from the outside.

### SUMMARY OF THE INVENTION

It is an object of the present invention to provide a semiconductor device that can facilitate the screening of semiconductor packages and a method of testing a semiconductor device.

To achieve the above-described object, the present invention is a semiconductor device in which a plurality of devices provided with mutually identical functions are stacked, wherein the devices each include:

a chip selection terminal by which the semiconductor device selects the device;

a prescribed terminal for generating a second internal signal that is selectively switched from a first internal signal according to the chip selection terminal; and

an input-switching circuit for selectively switching the first internal signal and the second internal signal.

In addition, the present invention is a method of testing a semiconductor device in which a plurality of devices provided with mutually identical functions are stacked, the method including steps of:

based on a signal controlled by a program that is written to a capacitive fuse unit contained in each of the plurality of devices, switching an internal signal produced by a chip selection terminal by which the semiconductor device selects the device to a signal generated by a prescribed terminal; and

carrying out a prescribed test after the internal signal has been switched.

The present invention as described above is of a configuration in which a first internal signal produced by the chip selection terminal by which the semiconductor device selects the device that is provided in each of the plurality of devices that are equipped with mutually identical functions and stacked in the semiconductor device and a second internal signal that is generated in the prescribed terminal and that is selectively switched from the first internal signal are selectively switched in an input-switching circuit, whereby screening of a stacked package can be facilitated.

The above and other objects, features, and advantages of the present invention will become apparent from the following description with reference to the accompanying drawings which illustrate an example of the present invention.

### BRIEF DESCRIPTION OF THE DRAWINGS

FIG. 1 shows the first embodiment of the semiconductor device of the present invention;

FIG. 2 is a timing chart for explaining the CSB switching operation in the semiconductor device shown in FIG. 1;

FIG. 3 is a timing chart for explaining the CSB switching operation in the case of sequential operation of using one capacitive fuse unit shown in FIG. 1 and then using the other capacitive fuse unit;

FIG. 4 shows the second embodiment of the semiconductor device of the present invention;

FIG. 5 shows the third embodiment of the semiconductor device of the present invention;

FIG. 6 shows the fourth embodiment of the semiconductor device of the present invention;

FIG. 7 is a timing chart for explaining the CSB switching operation in the embodiment shown in FIG. 6;

FIG. 8 shows the fifth embodiment of the semiconductor device of the present invention; and

FIG. 9 is a timing chart for explaining the CSB switching operation in the embodiment shown in FIG. 8.

### EXEMPLARY EMBODIMENT

The capacitive fuse unit described hereinbelow is capable of controlling signals that are supplied as output by an internally written program.

### First Embodiment

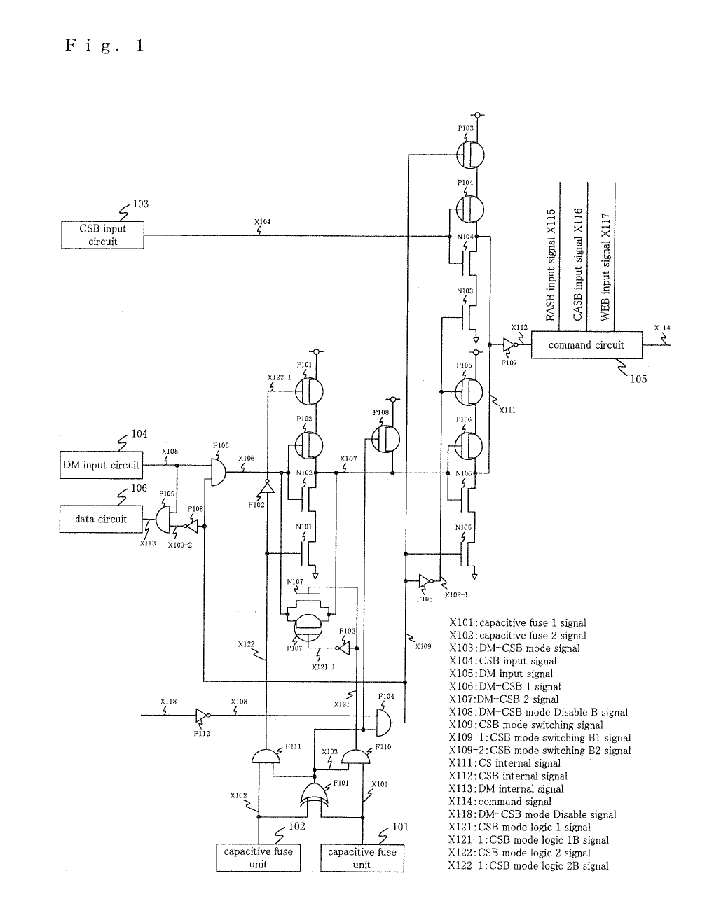

Referring to FIG. 1, the portion of the circuit is shown that illustrates the overall configuration of the CSB input switching modes in the input-switching circuit of the present invention. Explanation here regards a case in which CSB operation, which is normal operation according to standards, is replaced by DM, which is a data mask signal that is nonstandard. In other words, it is determined whether to bring about operation in a CSB mode that makes a CSB input signal, i.e., first internal signal, the internal selection signal, or to bring about operation in a DM mode that makes a DM input signal, i.e., the second internal signal, the internal selection signal. This DM is a signal (terminal) that is not normally used for measuring a semiconductor device.

When only capacitive fuse unit 101 is operated, capacitive fuse 1 signal X101 is supplied from capacitive fuse unit 101. Operating a capacitive fuse unit means that a prescribed signal is supplied from that capacitive fuse unit under the control of a program that is written in the capacitive fuse unit. Exclusive-OR F101 that is connected to capacitive fuse 1 signal X101 and capacitive fuse 2 signal X102 that is supplied from capacitive fuse unit 102 receives capacitive fuse 1 signal X101 as input and supplies DM-CSB mode signal X103 as output.

AND F110 that has received as input DM-CSB mode signal X103 and capacitive fuse I signal X101 supplies CSB mode logic 1 signal X121. CSB mode logic 1 signal X121 is applied as input to the gate of N-type transistor N 107 of the transfer gate that connects DM-CSB 1 signal X106 and DM-CSB 2 signal X107. In addition, inverted logic F103 of CSB mode logic 1 signal X121 supplies CSB mode logic 1B signal X121-1. CSB mode logic 1B signal X121-1 is applied as input to the gate of P-type transistor P107 of the transfer gate that connects DM-CSB 1 signal X106 and DM-CSB 2 signal X107. DM-CSB 1 signal X106 and DM-CSB 2 signal X107 can thereby be linked in phase.

DM-CSB mode signal X103 that is supplied from exclusive-OR F101 is applied as input to the gate of P-type transistor P108 that has its drain connected to DM-CSB 2 signal X107, whereby P-type transistor P108 is disabled to fix the potential of CSB2 signal X107.

In addition, DM-CSB mode Disable signal X118 is applied as input to inverted logic F112. This DM-CSB mode Disable signal X118 is a signal for enabling DM input signal X105. AND F104 is obtained for DM-CSB mode Disable B signal X108 that is supplied from inverted logic F112 and DM-CSB mode signal X103 and CSB mode switching signal X109 is supplied as output. AND F106 is then taken of CSB mode switching signal X109 that has been supplied and DM input signal X105 that is supplied from DM input circuit 104 that is connected to a prescribed terminal belonging to the semiconductor device, whereby AND F106 supplies the input of DM input signal X105 to DM-CSB 1 signal X106. In addition, CSB mode switching signal X109 is applied as input to inverted logic F108. AND F109 is taken of CSB mode switching B2 signal X109-2 that is supplied from inverted logic F1108 and DM input signal X105, whereby AND F109 does not supply the input of DM input signal X105 to DM internal signal X113 that is linked to data circuit 106 to which DM input signal X105 is connected in normal operations.

Further, CSB mode switching signal X109 is applied as input to: the gate of P-type transistor P103 that is vertically-connected to the source side of P-type transistor P104 of inverted logic that receives CSB input signal X104 as input, which is a chip selection signal received as input from the chip selection terminal belonging to that semiconductor device for selecting the semiconductor and that is supplied from CSB input circuit 103; and to the gate of N-type transistor N105 that is vertically-connected to the source side of N-type transistor N106 of inverted logic that receives as input DM-CSB 2 signal X107. In this case, “vertical connection” is connection between the source of one transistor and the drain of another transistor.

CSB mode switching signal X109 is further applied as input to inverted logic F105, and CSB mode switching B1 signal X109-1 is supplied from inverted logic F105. CSB mode switching B1 signal X109-1 that is supplied as output is applied as input to: the gate of N-type transistor N103 that is vertically-connected to the source side of N-type transistor N104 of inverted logic that receives CSB input signal X104; and to the gate of P-type transistor P105 that is vertically-connected to the source side of P-type transistor P106 of inverted logic that receives DM-CSB 2 signal X107 as input. The signal that causes operation of CS internal signal X111 that is supplied from each of the inverted logic is then switched from CSB input signal X104 to DM-CSB 2 signal X107. These P-type transistors P103-P106 and N-type transistors N103-N106 make up the selector for selectively switching CSB input signal X104 and DM input signal X105.

CS internal signal X111 further passes through inverted logic F107 and becomes CSB internal signal X112, whereby the polarity that was inverted by the inverted logic that received CSB mode switching signal X109 as input is returned to the original polarity, and the CSB internal signal X112 is then applied as input to command circuit 105. In other words, this CSB internal signal X112 is a selection signal for selecting the device to be measured. RASB input signal X115, which is a signal for conveying the timing that gives the row address to memory, CASB input signal X116, which is a signal for conveying the timing that gives the column address to memory, and WEB input signal X117, which is a signal for conveying the timing for writing data to memory, are applied as input to command circuit 105. Command signal X114 is generated based on these command-system signals and CSB internal signal X112 and supplied as output.

On the other hand, when only capacitive fuse unit 102 is operated, capacitive fuse 2 signal X102 is supplied as output. AND F111 is taken of capacitive fuse 2 signal X102 and DM-CSB mode signal X103 and CSB mode logic 2 signal X122 is supplied as output. CSB mode logic 2 signal X122 is applied as input to the gate of N-type transistor N101 that is vertically-connected to the source side of N-type transistor N102 of inverted logic that receives DM-CSB 1 signal X106 as input. In addition, inverted logic 102 is taken of CSB mode logic 2 signal X122 and CSB mode logic 2B signal X122-1 is supplied as output. CSB mode logic 2B signal X122-1 is applied to the gate of P-type transistor P101 that is vertically-connected to the source side of P-type transistor P102 of inverted logic that receives DM-CSB 1 signal X106 as input, whereby DM-CSB 1 signal X106 and DM-CSB 2 signal X107 can be linked in opposite phases. The operations are otherwise the same as for operations when only capacitive fuse unit 101 is operated with the exception of the control of transfer gates N107 and P107. These P-type transistors P101-P102 and P107 and N-type transistors N101-N102 and N107 are the polarity control unit for controlling the polarity of DM input signal X105.

The CSB operating mode according to DM that has become nonstandard due to the capacitive fuse unit can be returned to CSB within normal operating standards. From a state in which one capacitive fuse unit of either of capacitive fuse unit 101 and capacitive fuse unit 102 is in operation, both capacitive fuse units are placed in operation. Exclusive-OR F101 receives both of capacitive fuse 1 signal X101 and capacitive fuse 2 signal X102 as input and halts the output of DM-CSB mode signal X103 that is being supplied.

Accordingly, the output is halted of all of CSB mode logic 1 signal X121 of AND F110, CSB mode logic 2 signal X122 of AND F111, and output signal CSB mode switching signal X109 of AND F104 that are receiving DM-CSB mode signal X103 as input.

Accordingly, N-type transistor N101 that receives CSB mode logic 2 signal X122 at its gate, P-type transistor P101 that receives CSB mode logic 2B signal X122-1 at its gate, N-type transistor N107 that receives CSB mode logic 1 signal X121 at its gate, and P-type transistor P107 that receives CSB mode logic 1B signal X121-1 at its gate are all disabled. DM-CSB 1 signal X106 and DM-CSB 2 signal X107 are then cut off. In addition, P-type transistor P108 that receives DM-CSB mode signal X103 at its gate is enabled, and DM-CSB 2 signal X107 that has been cut off is fixed at potential VDD.

At the same time, the output of CSB mode switching signal X109 from AND F104 is halted. In addition, the output of AND F106 that receives CSB mode switching signal X109 as input is halted. Still further, AND F109 that receives CSB mode switching B2 signal X109-2 that operates complementary to CSB mode switching signal X109 is enabled, and the response of DM input signal X105 is switched from DM-CSB 1 signal X106 to DM internal signal X113.

Still further, CSB mode switching signal X109 enables P-type transistor P103 that is vertically-connected to the source of P-type transistor P104 of inverted logic that is made up by P-type transistor P104 and N-type transistor N104 that receive CSB input signal X104 as input. CSB mode switching signal X109 further disables N-type transistor N105 that is vertically-connected to the source of N-type transistor N106 of inverted logic that is made up from P-type transistor P106 and N-type transistor N106 that receive DM-CSB 2 signal X107. At the same time, CSB mode switching B1 signal X109-1 that operates complementary to CSB mode switching signal X109 enables N-type transistor N103 that is vertically-connected to the source of N-type transistor N104 of inverted logic that is made up from P-type transistor P104 and N-type transistor N104. CSB mode switching signal X109 further disables P-type transistor P105 that is vertically-connected to the source of P-type transistor P106 of inverted logic that is made up from P-type transistor P106 and N-type transistor N106. As a result, the signal that is the basis of CS internal signal X111 is switched from DM-CSB 2 signal X107 to CSB input signal X104, the overall logic of DM-CSB is disabled, and operations can be returned to CSB within normal operating standards.

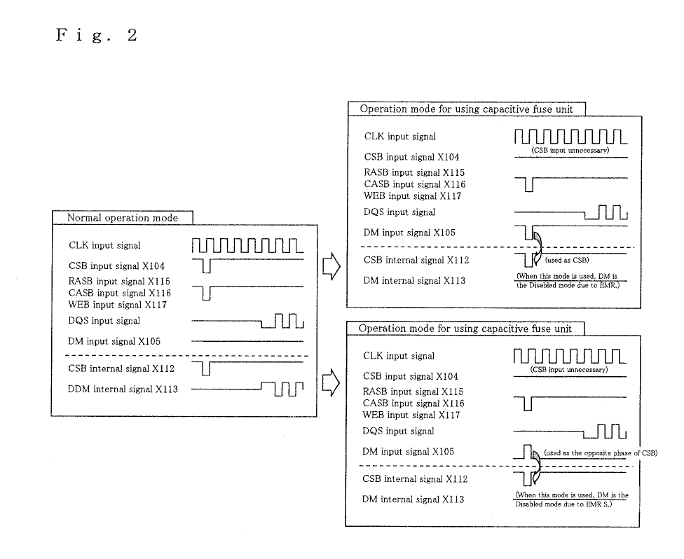

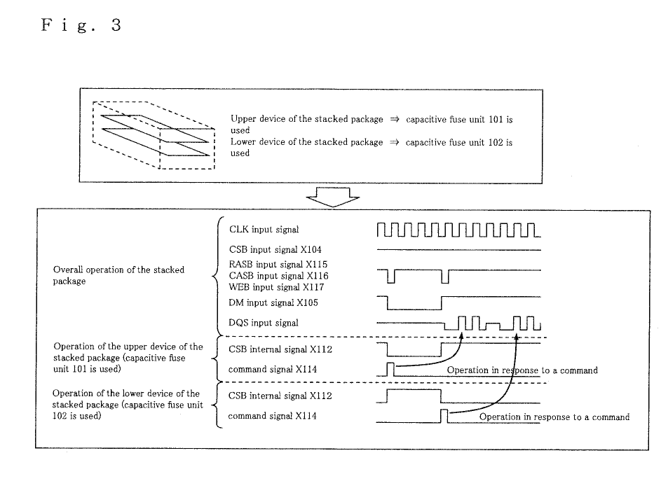

Explanation next regards the CSB switching operation in the semiconductor device shown in FIG. 1 with reference to FIGS. 2 and 3.

Explanation first regards the normal operating mode.

Matched to the timing of the rise to the high level of CLK input signal, which is the clock received as input for causing operation of the present embodiment, CSB input signal X104 is set to low level similar to RASB input signal X115, CASB input terminal X116, and WEB input signal X117. As a result, RASB input signal X115, CASB input signal X116, and WEB input signal X117 are taken inside. In other words, an operating command is generated by the combination of RASB input signal X115, CASB input signal X116, and WEB input signal X117 that become low at the time that the level of CLK input signal becomes high. At this time, DM input signal X105 is not operated when an entry is being made to a mode register set that does not use DM. On the other hand, according to this mode, when an entry is being made to a mode register set that uses DM, DM input signal X105 is operated only during read matched to a DQS input signal, which is a data strobe signal.

Explanation next regards the operating mode when the present invention is adopted. The operation of CLK input signal, RASB input signal X115, CASB input signal X116, WEB input signal X117, and DM input signal 105 is the same as the normal operating mode.

When capacitive fuse unit 101 is placed in operation, the signal that is the basis of CS internal signal X111 is switched from CSB input signal X104 to DM-CSB 2 signal X107. DM-CSB 1 signal X106 is enabled by AND F106, DM internal signal X113 is disabled by AND F109, and DM-CSB 1 signal X106 is connected in phase with DM-CSB 2 signal X107. As a result, DM input signal X105 can be caused to operate as a substitute signal of CSB input signal X104 identically to CSB of the normal operating mode.

When capacitive fuse unit 102 is next placed in operation, the signal that is the basis of CS internal signal X111 switches from CSB input signal X104 to DM-CSB 2 signal X107. In addition, DM-CSB 1 signal X106 is enabled by AND F106, DM internal signal X113 is disabled by AND F109, and DM-CSB 1 signal X106 is connected by the opposite phase of DM-CSB 2 signal X107. As a result, DM input signal X105 can be caused to operate in the opposite phase of the normal operating mode as a substitute signal of the opposite phase of CSB input signal X104.

The following operations are possible when conducting measurement of a stacked package in the measurement environment of a monolayer package by these circuit characteristics.

As shown in FIG. 3, capacitive fuse unit 101 is used in the upper device of a stacked package and capacitive fuse unit 102 is used in the lower device of the stacked package. By means of the previously described circuit characteristics, in the upper device that uses capacitive fuse unit 101, the function of CSB input signal X104 is switched to DM input signal X105 that is in phase with CSB input signal X104, following which a test is carried out upon the upper device. On the other hand, in the lower device that uses capacitive fuse unit 102, the function of CSB input signal X104 is switched to DM input signal X105 in the opposite phase of CSB input signal X104, following which a test is carried out upon the lower device. When using a stacked package in the measurement environment of a monolayer package, DM pins that are connected in the stacked package can be used without using the CSB pins that are not connected in the stacked package. First, in the present invention, DM pins are used in place of CSB pins, and DM pins are therefore disabled by means of EMR S commands.

When setting EMR S, capacitive fuse unit 101 and capacitive fuse unit 102 are both already effective. As a result, CSB input signal X104 cannot be used, and implementation is by DM input signal X105 that is switched from CSB. During standby of a device in which EMR S setting is possible, output of DM is not effected, and as a result, when the DM of the upper device is disabled, DM is received at low level and EMR S is implemented. A case in which the lower device is disabled can be handled by receiving DM at high level.

When the EMR S setting is completed, the input of each of the commands RASB input signal X115, CASB input signal X116, and WEB input signal X117 is carried out as described below.

When the upper device is to be selected, DM is received at low level at the timing of the CLK at which the command is received. When the lower device is to be selected, DM is received at high level at the timing of the CLK at which the command is received. By means of this mode, the selection of the upper devise or lower device can be effected by the input of DM at high level or low level. In addition, the upper device and lower device can be tested independently using pins that are connected with the stacked package even in the measurement environment of a monolayer package.

These operations further employ the capacitive fuse unit that is not being used, i.e., use capacitive fuse unit 101 and capacitive fuse unit 102 at the same time. It is therefore possible to return to the operation of CS internal signal X111 according to CSB input signal X104 from the operation of CS internal signal X111 according to DM-CSB 2 signal X107, and operation as the normal operating mode can be brought about.

### Second Embodiment

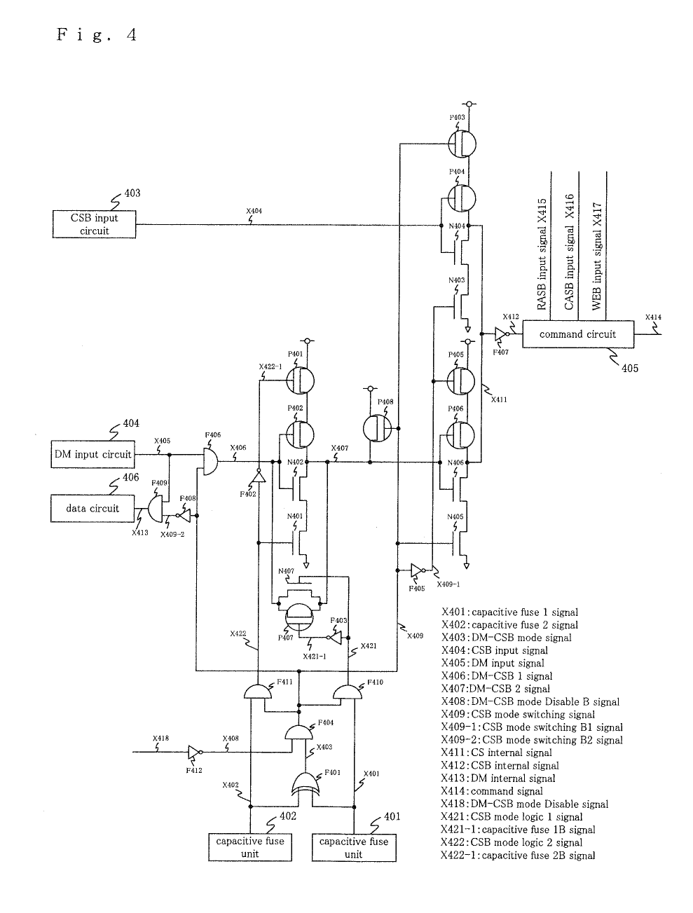

Referring to FIG. 4, the part of the present embodiment that differs from the first embodiment is the input position of DM-CSB mode Disable signal X418 (Test mode DM-CSB mode Disable signal X118 in FIG. 1). In the first embodiment, the original signal of CS internal signal X111 is applied as input to only the portion that switches between CSB input signal X104 and DM-CSB 2 signal X107. In other words, even if DM-CSB mode Disable signal X118 is enabled, there is no change in the connection logic portion of DM-CSB 1 signal X106 and DM-CSB 2 signal X107, and only the original signal of CS internal signal X111 is switched from DM-CSB 2 signal X107 to CSB input signal X104, whereby the change to the normal operation mode is carried out by means of DM-CSB mode Disable signal X118.

In the second embodiment, on the other hand, DM-CSB mode Disable signal X418 takes output DM-CSB mode signal X403 that takes exclusive-OR F401 of capacitive fuse 1 signal X401 and capacitive fuse 2 signal X402. As a result, when DM-CSB mode Disable signal X418 is enabled, AND F410 is implemented that supplies as output CSB mode logic 1 signal X421 that is switched by capacitive fuse unit 401. In addition, AND F411 that is switched by capacitive fuse unit 402 and that supplies CSB mode logic 2 signal X422 and AND F406 that receives DM input signal X405 and supplies DM-CSB 1 signal X406 are disabled. P-type transistor P408 that receives CSB mode switching signal X409 at its gate and that has its drain connected to DM-CSB 2 signal X407 is enabled. As a result, fixing DM-CSB 2 signal X407 to high level, not only switches the original signal of CS internal signal X411 that has returned to the normal operating mode in the first embodiment, but also enables a return to the state of the normal operation mode even in the connected logic portion of DM-CSB 1 signal X406 and DM-CSB 2 signal X407 that accords with capacitive fuse unit 401 and capacitive fuse unit 402 that did not return to the state of normal operation mode in the first embodiment. In regard to the other circuits, signals, and logic, the operations of components in which the two lower places of reference numbers are the same as the two lower places of reference numbers in the first embodiment are identical to the operations of the respective components in the first embodiment.

This second embodiment enables a suppression of the operating current when DM-CSB mode Disable signal X418 is used. Other operations that do not use DM-CSB mode Disable signal X418 are similar to the content of the first embodiment.

### Third Embodiment

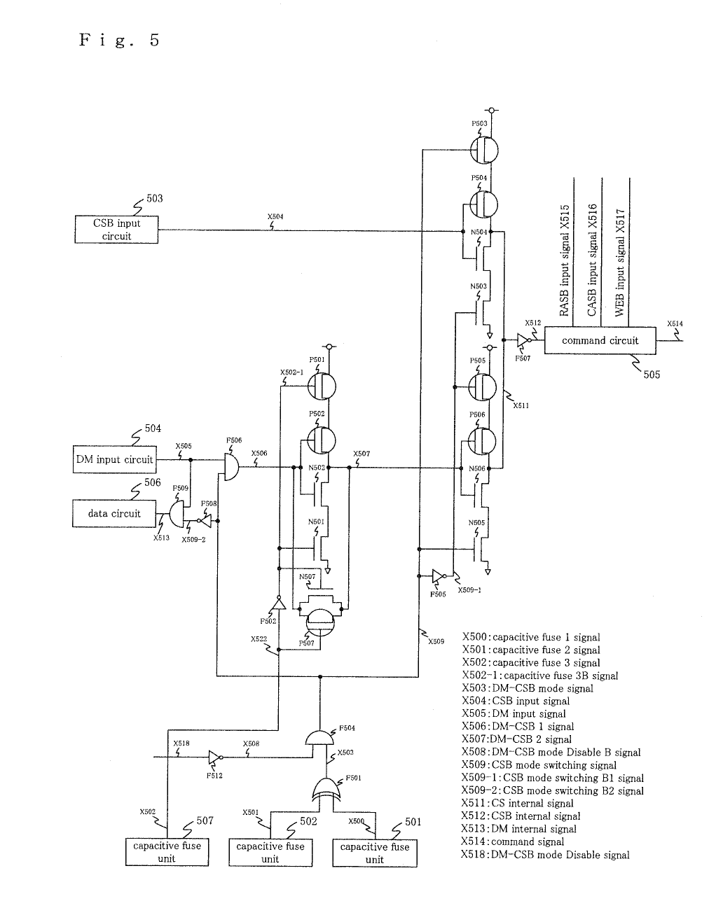

Referring to FIG. 5, a form is shown that uses a method of dividing by which capacitive fuse unit 501 and capacitive fuse unit 502 are used in DM-CSB mode switching and capacitive fuse unit 507 is used in logic import of DM input circuit 504.

When capacitive fuse unit 501 is used, input is applied to exclusive-OR F501 and DM-CSB mode signal X503 is supplied as output. DM-CSB mode signal X503 takes the AND with DM-CSB mode Disable B signal X508 and supplies CSB mode switching signal X509 as output.

CSB mode switching signal X509 enables DM-CSB 1 signal X506 by means of AND F506, and further, by passing by way of CSB mode switching B signal X509-2 that operates complementary to CSB mode switching signal X509, disables DM internal signal X513 by means of AND F509. In addition, applying CSB mode switching signal X509 to the gate of P-type transistor P503 that is vertically-connected to the source side of P-type transistor P504 of inverted logic that receives CSB input signal X504 as input and to the gate of N-type transistor N505 that is vertically connected to the source side of N-type transistor N506 of inverted logic that receives DM-CSB 2 signal X507 as input switches the original signal of CS internal signal X511 from CSB input signal X504 to DM-CSB 2 signal X507.

Operation is similar when capacitive fuse unit 502 is used and capacitive fuse unit 501 is not used. At this time, DM-CSB 1 signal X506 that is generated from DM input signal X505 passes by way of the transfer gate that is made up from P-type transistor P507 and N-type transistor N507 and the logic with DM-CSB 2 signal X507 is therefore in phase.

Using capacitive fuse unit 507 causes capacitive fuse 3 signal X502 to become high level and capacitive fuse 3B signal X502-1 that operates complementary to capacitive fuse 3 signal X502 to become low level, whereby the transfer gate made up from P-type transistor P507 and N-type transistor N507 is disabled. Using capacitive fuse unit 507 further enables P-type transistor P501 and N-type transistor N501 that are vertically-connected on the source side to inverted logic that is made up from P-type transistor P502 and N-type transistor N502. As a result, DM-CSB 1 signal X506 and DM-CSB 2 signal X507 can be placed in opposite phases.

Returning the CSB mode to its original state can be handled by simultaneously using capacitive fuse unit 501 and capacitive fuse unit 502. The outputs of each are applied as input to exclusive-OR F501 and the output DM-CSB mode signal X503 is disabled. AND F504 that receives DM-CSB mode signal X503 as input disables CSB mode switching signal X509, whereby DM-CSB 1 signal X506 is disabled and DM internal signal X513 is enabled. As a result, the original signal of CS internal signal X511 is switched from DM-CSB 2 signal X507 to CSB input signal X504, and the CSB mode returns to its original state. The operation is the same when using the test mode of DM-CSB mode Disable signal X504. Regarding other circuits, signals, and logic, the operations of components for which the lower two places of the reference number is the same as the lower two places of the reference number in the first embodiment are the same as the respective components in the first embodiment.

### Fourth Embodiment

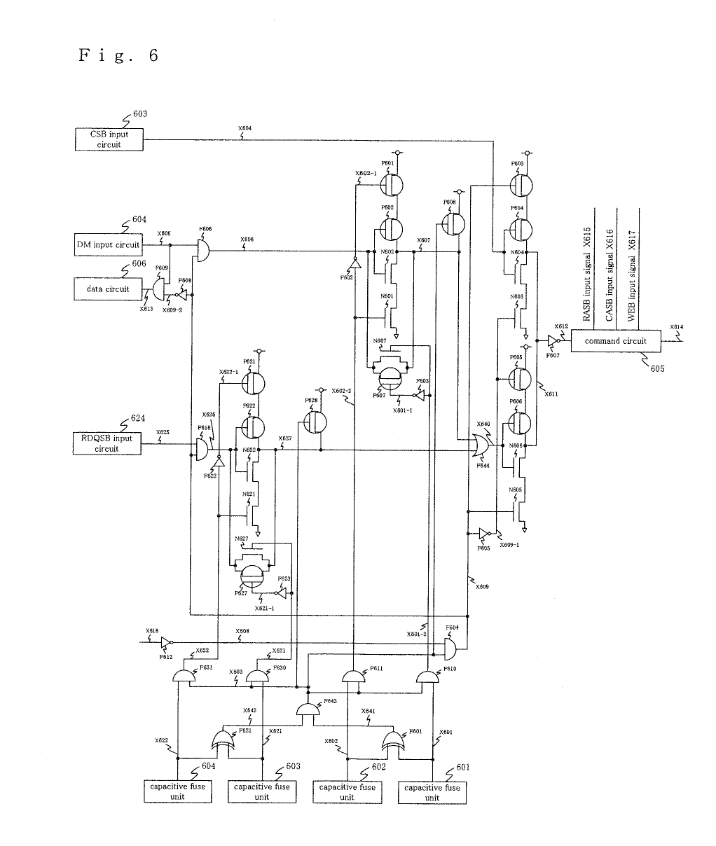

Referring to FIG. 6, an embodiment is shown that is based on the first embodiment and that is applied to three or more stacked packages instead of only two stacked packages.

To the set of: capacitive fuse unit 101, capacitive fuse unit 102, capacitive fuse 1 signal X101, capacitive fuse 2 signal X102, exclusive-OR F101, AND F110, AND F111, DM-CSB mode signal X103, CSB mode logic 1 signal X121, CSB mode logic 2 signal X122, CSB mode logic 1B signal X121-1, inverted logic F103, P-type transistor P107, N-type transistor N107, CSB mode logic 2B signal X122-1, inverted logic F102, P-type transistors P101 and P102, N-type transistors N101 and N102, P-type transistor P108, AND F106, DM input signal X105, and DM input circuit 104 shown in FIG. 1, another set is added. DM is changed to RDQSB, which is a read data strobe signal that is outside the standards of CSB operation, which is standard operation that accords with standards (because there is actually no input circuit in RDQSB, an input circuit similar to DM is newly provided). Signal X607 and signal X627 that correspond to DM-CSB 2 signal X107 are applied as input to AND F644 and signal X640 is supplied as output. Signal X640 is applied as input to the gates of P-type transistor P606 and N-type transistor N606 that correspond to P-type transistor P106 and N-type transistor N106 shown in FIG. 1. DM-CSB mode signal X641 and DM-CSB mode signal X642 that correspond to DM-CSB mode signal X103 are applied as input to AND F643 and signal X603 is supplied as output. Signal X603 is a signal that corresponds to DM-CSB mode signal X103 shown in FIG. 1. In the present embodiment, up to four layers can be handled. As many as eight layers can be handled by adding yet another set of additional circuits. Regarding the other circuits, signals, and logic, the operations of components for which the lower two places of reference numbers are identical to the lower two places of reference numbers in the first embodiment are identical to the respective components in the first embodiment. In addition, regarding the set that is added from the first embodiment, corresponding signals and logic operate in the same way.

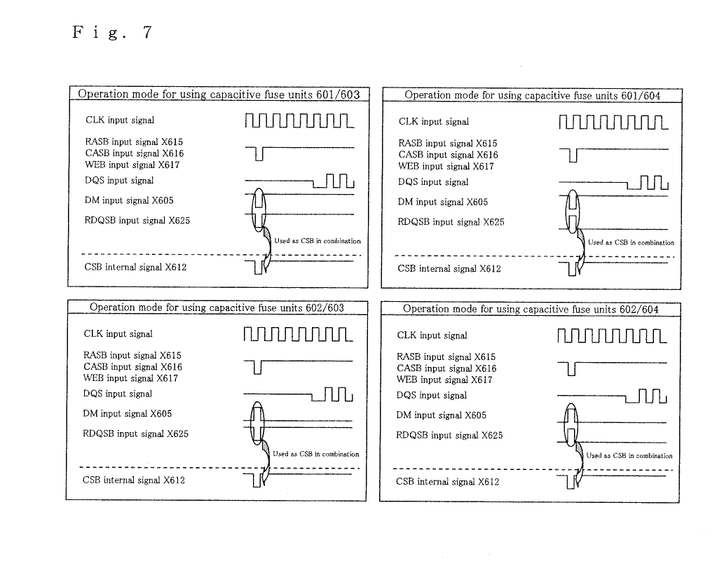

Explanation next regards the CSB switching operation in the embodiment shown in FIG. 6 with reference to FIG. 7.

CS internal signal X611 can be enabled and the devices in the stacked package can be selected in the event of matching of the combination of the logic of signal X606 to signal X607 and the logic of signal X626 to signal X627 that are determined by capacitive fuse unit 601, capacitive fuse unit 602, capacitive fuse unit 603, capacitive fuse unit 604 and the combination of high and low levels of DM input signal X605 and RDQSB input signal X625. More specifically, a device is selected in the event of a combination of the polarities of DM input signal X605 and RDQSB input signal X625 by which signal X607 and signal X627 are both low level after the operation of either one of capacitive fuse unit 601 and capacitive fuse unit 602 and either one of capacitive fuse unit 603 and capacitive fuse unit 604.

### Fifth Embodiment

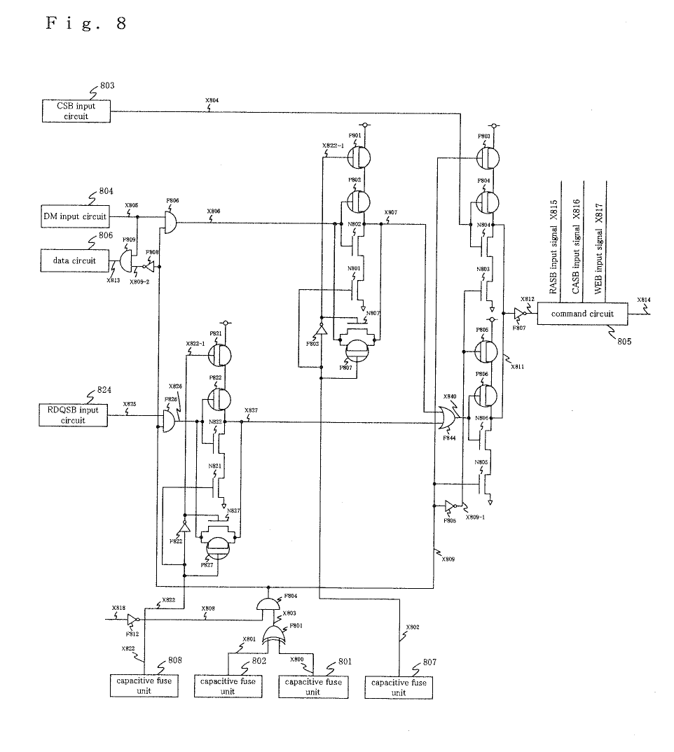

Referring to FIG. 8, an embodiment is shown that is based on the third embodiment for application to three or more stacked packages instead of only two stacked packages.

Another set is added to the set of: capacitive fuse unit 507, capacitive fuse 3 signal X502, AND F502, capacitive fuse 3B signal X502-1, P-type transistors P501, P502, and P507, N-type transistors N501, N502, and N507, DM-CSB 1 signal X506, DM-CSB 2 signal X507, AND F506, DM input signal X505, and DM input circuit 504. DM is changed to RDQSB (because there is actually no input circuit in RDQSB, an input circuit similar to DM is newly added). In addition, DM-CSB 2 signal X807 and DM-CSB 2 signal X827 that correspond to DM-CSB 2 signal X507 are applied as input to AND F844, and signal X840 is supplied as output. Signal X840 is applied as input to the gates of P-type transistor P806 and N-type transistor N806 that correspond to P-type transistor P506 and N-type transistor N506 shown in FIG. 5. Up to four layers can be handled in the present embodiment. Up to eight layers can be handled by adding yet another set of additional circuits. Finally, regarding the other circuits, signals, and logic, the operations of components for which the lower two places of references numbers are identical to the lower two places of the reference numbers in the third embodiment are identical to the operations of the respective components of the third embodiment. In addition, regarding the set that is added from the third embodiment, corresponding signals and logic have the same operation.

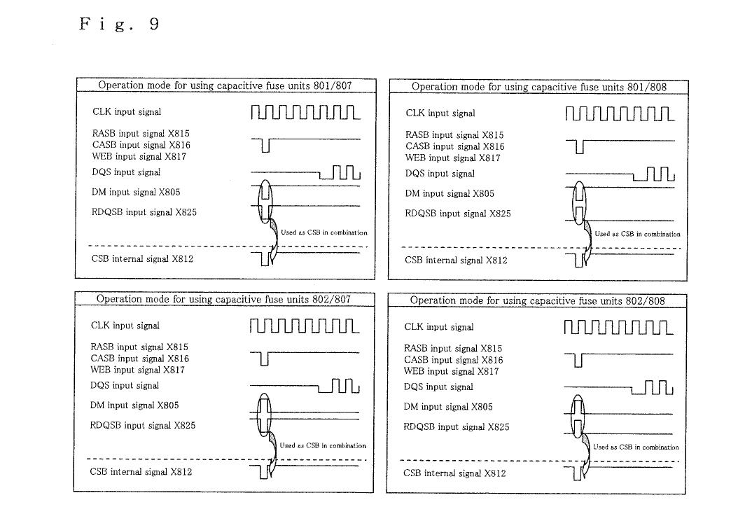

Explanation next regards the CSB switching operation in the embodiment shown in FIG. 8 with reference to FIG. 9.

CS internal signal X811 can be enabled in the event of matching of the combination of the logic of signal X806 to signal X807 and the logic of signal X826 to signal X827 that are determined by capacitive fuse unit 807 and capacitive fuse unit 808 and the combination of highs and lows of DM input signal X805 and RDQSB input signal X825. In addition, a device in the stacked package can be selected. More specifically, a device is selected in the event of a combination of polarities of DM input signal X805 and RDQSB input signal X825 for which both signal X807 and signal X827 are low level due to the logic of signal X806 to signal X807 and the logic of signal X826 and signal X827 that are determined by the combination of the operation of capacitive fuse unit 807 and capacitive fuse unit 808 following the operation of either one of capacitive fuse unit 801 and capacitive fuse unit 802.

As described hereinabove, the input-switching circuit of the semiconductor device of the present invention may include: a selector for selectively switching a first internal signal and a second internal signal, a polarity control unit for controlling the polarity of the second internal signal, and a capacitive fuse unit into which a program can be written for controlling the selector and the polarity control unit.

A device may include a plurality of prescribed terminals, and may include a number of input-switching circuits that accords with the number of devices provided in the semiconductor device.

A command circuit may be included for generating a command signal based on a signal supplied as output from an input-switching circuit and a command-system signal.

A step may be included of, after a test has been carried out, switching a signal generated by a prescribed terminal to an internal signal realized by a chip selection terminal based on a signal that is controlled by a program.

In the above-described embodiment, a capacitive fuse is used. An electrically controllable electrical fuse can be used in stead of the capacitive fuse.

The above-described present invention can greatly reduce the cost of equipment investment in post-processing test screening because, despite the advanced state of facilities for screening monolayer packages that are the mainstream of the related art, the state of facilities for stacked packages that have been popularized after the popularization of monolayer packages is in many cases not yet advanced. The measurement environments for stacked packages, which require more pins than monolayer packages, necessitate new investments in equipment, and the outlay for equipment investment required for stacked packages increases with increase in the number of mass-produced units. Although the use of the present invention still requires measurement environments for stacked packages in order to use capacitive fuse units, the stacked-package measurement time for using capacitive fuse units is negligible, and by enabling the implementation of other screening tests of stacked packages such as the screening of both the upper devices and lower devices of stacked packages in the measurement environments of conventional monolayer packages, the present invention can eliminate the need to produce a large number of measurement environments for stacked packages and can reduce the cost of investment in facilities for producing measurement environments for stacked packages.

While an exemplary embodiment of the present invention has been described in specific terms, such description is for illustrative purpose only, and it is to be understood that changes and variations may be made without departing from the spirit or scope of the following claims.

What is claimed is:

1. A semiconductor device wherein a plurality of devices provided with mutually identical functions are stacked, said devices comprising:
a chip selection terminal by which said semiconductor device selects one of said devices;
a prescribed terminal for generating a second internal signal that is selectively switched from a first internal signal according to said chip selection terminal; and
an input-switching circuit for selectively switching said first internal signal and said second internal signal.

2. A semiconductor device according to claim 1, wherein said input-switching circuit comprises:
a selector for selectively switching said first internal signal and said second internal signal;
a polarity control unit for controlling the polarity of said second internal signal; and
an electrical fuse unit to which a program can be written for controlling said selector and said polarity control unit.

3. A semiconductor device according to claim 2, wherein said electrical fuse unit comprises:
a capacitive fuse to which a program can be written for controlling said selector and said polarity control unit.

4. A semiconductor device according to claim 1, wherein said device comprises:
a plurality of said prescribed terminals; and
a number of said input-switching circuits that accords with the number of devices provided in said semiconductor device.

5. A semiconductor device according to claim 1, further comprising a command circuit for generating a command signal based on a signal supplied as output from said input-switching circuit and a command-system signal.

6. A method of testing a semiconductor device in which a plurality of devices provided with mutually identical functions are stacked, said method comprising steps of:
based on a signal controlled by a program that is written to an electrical fuse unit contained in each of said plurality of devices, switching an internal signal from a chip selection terminal by which said semiconductor device selects said device to a signal generated by a prescribed terminal; and
carrying out a prescribed test after the internal signal has been switched.

7. A method according to claim 6, further comprising a step of: after said test has been carried out and based on a signal controlled by said program, switching the signal generated by said prescribed terminal to an internal signal from said chip selection terminal.
